(19) United States
(12) Patent Application Publication
(10) Pub. No.: US 2025/0218800 A1
(43) Pub. Date: Jul. 3, 2025

(54) SEMICONDUCTOR DEVICE, SEMICONDUCTOR PACKAGE, AND PRINTED CIRCUIT BOARD HAVING A PATTERN

(71) Applicant: SAMSUNG ELECTRONICS CO., LTD., SUWON-SI (KR)

(72) Inventors: Yongkwan LEE, Suwon-si (KR); Tarkhyun KO, Suwon-si (KR); Junwoo PARK, Suwon-si (KR); Jinchan AHN, Suwon-si (KR); Kundae YEOM, Suwon-si (KR); Youngmin LEE, Suwon-si (KR); Wonhee LEE, Suwon-si (KR); Taejun JEON, Suwon-si (KR)

(21) Appl. No.: 18/973,227

(22) Filed: Dec. 9, 2024

(30) Foreign Application Priority Data
Dec. 27, 2023 (KR) 10-2023-0193174
Feb. 28, 2024 (KR) 10-2024-0029230

(51) Int. Cl. H01L 21/56; H01L 23/31

(52) U.S. Cl. CPC H01L 21/565; H01L 23/3107

(57) ABSTRACT

A semiconductor device includes: a semiconductor molding upper mold and a semiconductor molding lower mold, wherein a printed circuit board having a plurality of semiconductor devices mounted thereon is disposed on the semiconductor molding lower mold; and a cavity disposed between the semiconductor molding upper mold and the semiconductor molding lower mold, wherein the printed circuit board includes internal through holes and external through holes, wherein the external through holes are spaced apart from a position where the plurality of semiconductor devices are mounted, and the semiconductor molding lower mold has through holes that overlap the internal through holes and the external through holes.

### CROSS-REFERENCE TO RELATED APPLICATIONS

This application claims priority under 35 U.S.C. § 119 to Korean Patent Application Nos. 10-2023-0193174, filed on Dec. 27, 2023, and 10-2024-0029230, filed on Feb. 28, 2024, in the Korean Intellectual Property Office, the disclosures of which are incorporated by reference herein in their entireties.

### TECHNICAL FIELD

The present inventive concept relates to a semiconductor device, a semiconductor package, and a printed circuit board. More particularly, the present inventive concept relates to a semiconductor device, a semiconductor package, and a printed circuit board having a pattern.

### DISCUSSION OF THE RELATED ART

An underfill is a material that fills spaces that are between a substrate and a chip or between chips that are connected to each other by using a bump and that increases the reliability of a bonding portion. A process using an underfill may be divided into a process of filling spaces that are between bumps after a bonding process by using the bumps and a process of applying an underfill material to a bonding portion before a bonding process. The process of filling spaces that are between bumps after bonding may be classified into capillary underfill (CUF) and molded underfill (MUF) according to filling methods. Herein, CUF is a process of spraying an underfill material beside a chip by using capillaries such that the underfill material fills between the chip and a substrate by surface tension, and MUF is a process of allowing an epoxy molding compound (EMC) material used for molding to perform an underfill function while the molding.

### SUMMARY

According to embodiments of the present inventive concept, a semiconductor device includes: a semiconductor molding upper mold and a semiconductor molding lower mold, wherein a printed circuit board having a plurality of semiconductor devices mounted thereon is disposed on the semiconductor molding lower mold; and a cavity disposed between the semiconductor molding upper mold and the semiconductor molding lower mold, wherein the printed circuit board includes internal through holes and external through holes, wherein the external through holes are spaced apart from a position where the plurality of semiconductor devices are mounted, and the semiconductor molding lower mold has through holes that overlap the internal through holes and the external through holes.

According to embodiments of the present inventive concept, a semiconductor package includes: a printed circuit board including internal through holes and external through holes; a plurality of semiconductor devices mounted on the printed circuit board; and an encapsulation material sealing a space that is between the printed circuit board and the plurality of semiconductor devices, wherein the internal through holes are disposed under the plurality of semiconductor devices, respectively, and the external through holes are disposed outside an area in which the plurality of semiconductor devices are mounted.

According to embodiments of the present inventive concept, a printed circuit board includes: an upper surface, on which a plurality of semiconductor devices are mounted, and a lower surface that is opposite to the upper surface; internal through holes disposed under the plurality of semiconductor devices, respectively; and first external through holes disposed outside an area in which the internal through holes are arranged, wherein each of the first external through holes has a diameter that is greater than a diameter of each of the internal through holes.

### BRIEF DESCRIPTION OF THE DRAWINGS

The above and other aspects of the present inventive concept will become more apparent by describing in detail embodiments thereof, with reference to the accompanying drawings, in which:

FIG. 1 is a cross-sectional view illustrating a molding apparatus, in which a printed circuit board (PCB) is seated, and flow of an encapsulation material in a molding process, according to embodiments of the present inventive concept;

FIG. 2 is a cross-sectional view illustrating a flow of voids in the molding process of FIG. 1;

FIG. 3A is a cross-sectional view illustrating the molding apparatus of FIG. 1 that is filled with an encapsulation material;

FIG. 3B is a top view of a molded PCB of FIG. 3A;

FIG. 4 is a magnified cross-sectional view of a portion “EX” of FIG. 3B; and

FIG. 5 is a top view of a PCB pattern according to embodiments of the present inventive concept.

### DETAILED DESCRIPTION OF THE EMBODIMENTS

Hereinafter, embodiments of the present inventive concept are described in detail with reference to the accompanying drawings. Like reference numerals in the drawings denote like elements, and thus, their repetitive description will be omitted or briefly discussed.

Various kinds of change or modification and various changes in form may be applied to the embodiments of the present inventive concept, and embodiments of the present inventive concept will be illustrated in the drawings and described in detail in the specification. However, it should be understood that the embodiments do not limit the scope of the present inventive concept but include every modification, equivalent, or replacement within the disclosed spirit and technical scope.

When it is described that a certain element or layer is located “on” or “connected” to another element or layer, it may be understood that the certain element may be located “on” or “connected” to another element directly or via another element disposed therebetween. In contrast, when a certain element is “directly on” or “directly connected” to another element, it should be understood that any other element or layer does not exist therebetween.

The spatially relative terms, such as “below”, “beneath”, “lower”, “above” and “upper,” can be used herein for describing a relationship of certain devices or elements with respect to other devices or elements as illustrated in the drawings. It can be understood that the spatially relative terms intend to include other directions of a device while using or operating the device in addition to a direction described in the drawings. For example, if a device is turned over in the drawings, elements described to exist “below” or “beneath” other elements may be “above” the other elements. Therefore, for example, the term “below” may include both directions of “below” and “on”. A device may also be arranged in a different direction, and accordingly, the spatially relative terms may be interpreted according to arrangement.

The terminology used in the specification is used only to describe embodiments and does not have any intention to limit the present inventive concept. In the specification, an expression in the singular includes an expression in the plural unless they are clearly different from each other in context.

Although terms, such as ‘first’ and ‘second’, can be used to describe various devices or elements, the devices or elements are not limited by the terms. The terms are used to distinguish a certain device or element from another device or element. Therefore, a first device or element can be named a second device or element without departing from the technical idea of the present inventive concept.

All terms (including technical and scientific terms) used herein have the same meaning as those generally understood by those of ordinary skill in the art unless they are defined differently.

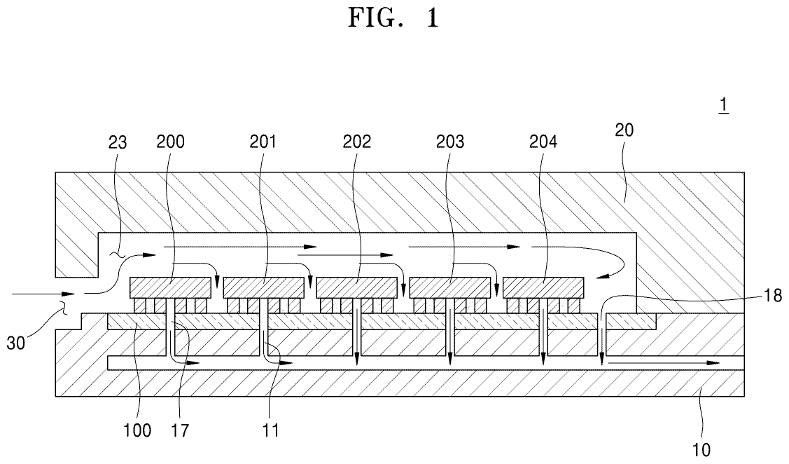

A semiconductor molding mold in which a printed circuit board (PCB) is mounted, according to an embodiment of the present inventive concept, is described with reference to FIGS. 1, 2, and 3A.

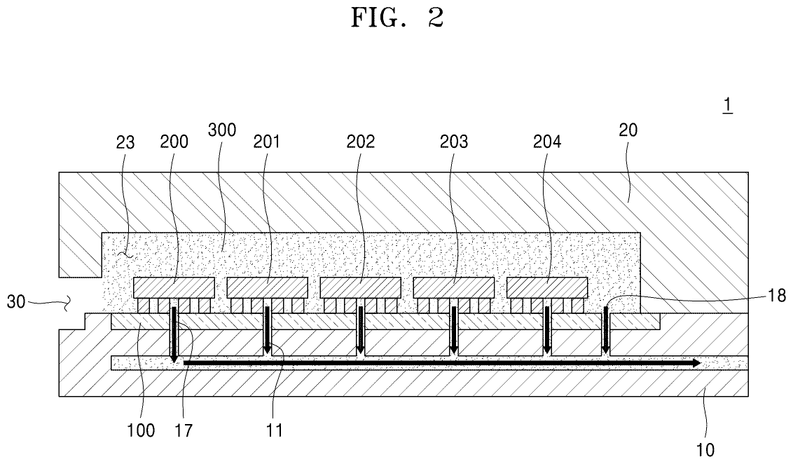

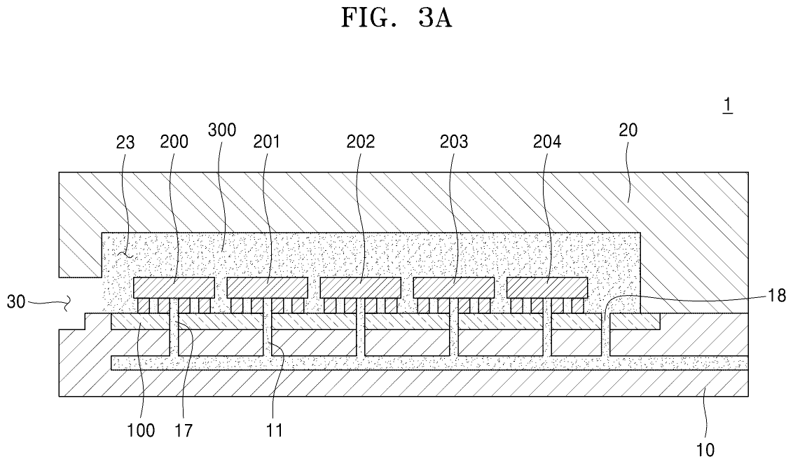

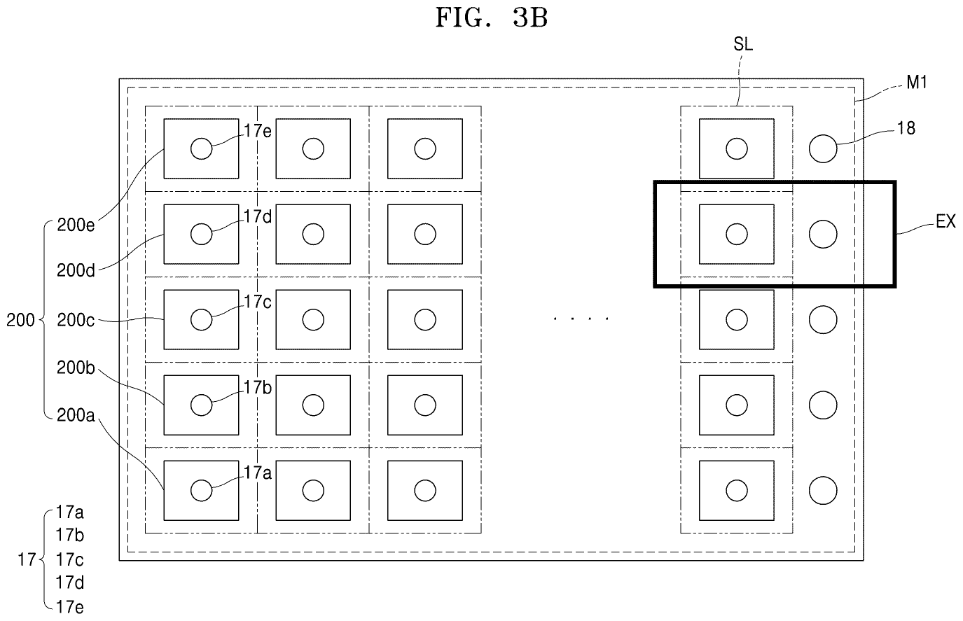

FIG. 1 is a cross-sectional view illustrating a molding apparatus 1, in which a PCB 100 is seated, and a path along which an encapsulation material flows in a cavity 23 in a molding process, according to an embodiment of the present inventive concept. FIG. 2 is a cross-sectional view illustrating a flow of voids in the molding apparatus 1 of FIG. 1. FIG. 3A is a cross-sectional view illustrating the molding apparatus 1 of FIG. 1 that is filled with an encapsulation material 300.

Referring to FIG. 1, the molding apparatus 1 may include a semiconductor molding upper mold 20, a semiconductor molding lower mold 10, and a runner 30.

The molding apparatus 1 may be used in a semiconductor molding process. A molding process is a process of sealing a semiconductor device, a circuit board, and the like by using an encapsulation material. For example, the molding process may be a process of completely sealing a device and the like by using an encapsulation material, for effective dissipation of heat that is generated from a circuit board while protecting circuit devices from a plurality of causes, such as erosion due to air or the outside, and ensuring mechanical stability.

Referring back to FIG. 1, the cavity 23 is formed under the semiconductor molding upper mold 20 of the molding apparatus 1. In the molding process, the encapsulation material may flow into the cavity 23 to seal semiconductor devices 200, 201, 202, 203, and 204, and the volume of a semiconductor product may be determined according to the size of the cavity 23. The size and the area of the cavity 23 may vary according to the type, the size, the usage, and the like of a semiconductor device.

Next, the PCB 100 may be seated on the semiconductor molding lower mold 10. The semiconductor devices 200, 201, 202, 203, and 204 may be mounted on the PCB 100. The semiconductor devices 200, 201, 202, 203, and 204 may be, for example, flip chips, but the present inventive concept is not limited thereto.

The PCB 100 may have internal through holes 17 and external through holes 18. The internal through holes 17 and the external through holes 18 may be a certain pattern of grooves in the PCB 100.

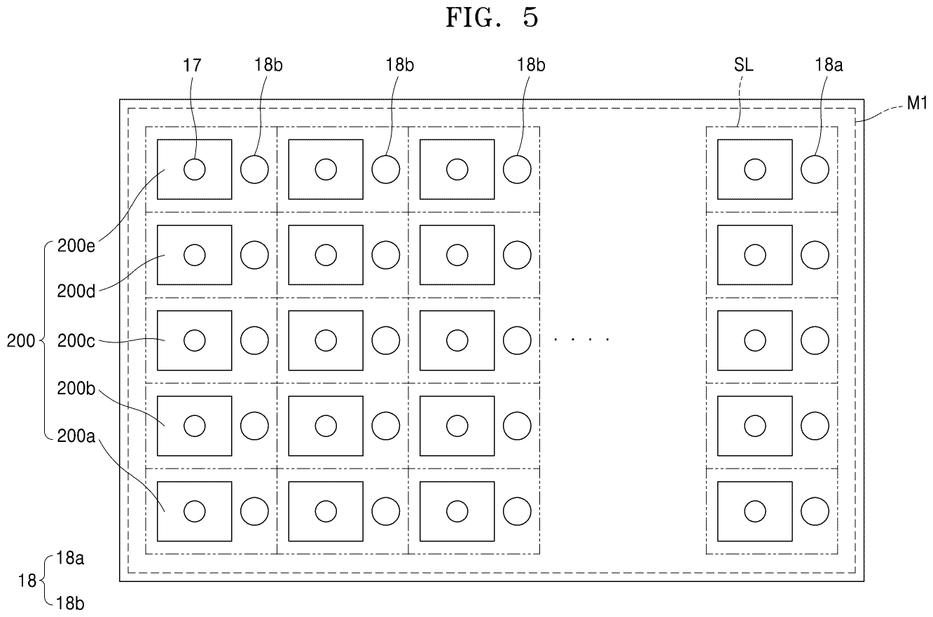

When a portion through which the encapsulation material is injected is defined as an entrance of the runner 30, the external through holes 18 may be only in a region far from the entrance of the runner 30. For example, when the entrance of the runner 30 is named “front” and the direction opposite thereto is named “back”, the external through holes 18 may be only in the back region. This may be because of a method of sealing semiconductor devices by injecting the encapsulation material. The encapsulation material that is injected through the entrance may flow backward to fill spaces that are between the semiconductor devices 200, 201, 202, 203, and 204 and the internal and external through holes 17 and 18. Voids, which may occur in this case, may also move in the direction in which the encapsulation material flows and be discharged to the outside through the internal through holes 17 and/or the external through holes 18. Because voids may be discharged to the outside along with flow of the encapsulation material, even though no external through holes 18 are arranged in a front region, voids may be removed by the internal through holes 17 that are arranged in the whole region and/or the external through holes 18 that are arranged in the back region. However, the present inventive concept is not limited thereto, and the external through holes 18 may also be between the internal through holes 17. A case where the external through holes 18 are arranged even in the front region is described below with reference to FIG. 5.

In embodiments of the present inventive concept, the internal through holes 17 may be formed at positions included in an area in which the semiconductor devices 200, 201, 202, 203, and 204 are arranged, in the vertical direction. In embodiments of the present inventive concept, the external through holes 18 may be arranged outside the area in which the semiconductor devices 200, 201, 202, 203, and 204 are arranged, in the vertical direction. However, the present inventive concept is not limited thereto, and some of the external through holes 18 may be arranged to overlap the semiconductor devices 200, 201, 202, 203, and 204 in the vertical direction. The sizes, the arrangement positions, and the like of the internal through holes 17 and the external through holes 18 are described below in detail.

Referring to FIG. 2, the runner 30 may be disposed between the semiconductor molding upper mold 20 and the semiconductor molding lower mold 10. To seal the semiconductor devices 200, 201, 202, 203, and 204, the encapsulation material 300 may be injected into the cavity 23 through the runner 30 and discharged to the outside through a window pattern 11 by passing through the internal through holes 17 and the external through holes 18 of the PCB 100. Voids that are formed inside the molding apparatus 1 may also be discharged in the direction in which the encapsulation material 300 is injected and discharged.

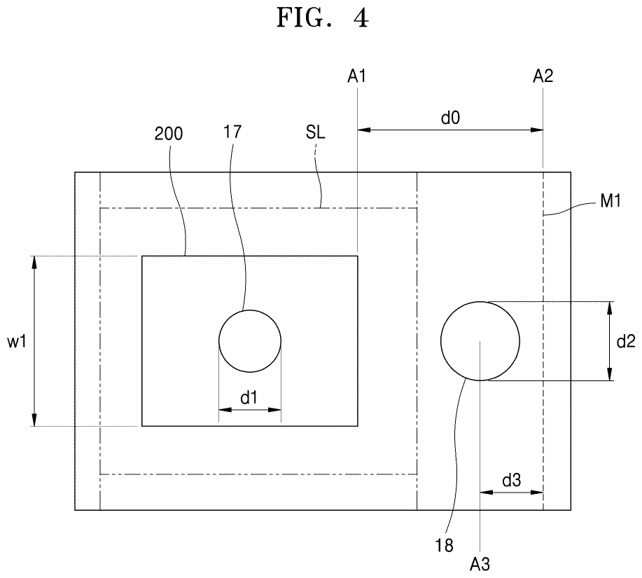

The window pattern 11 may be disposed beneath the internal through holes 17, on which the semiconductor devices 200, 201, 202, 203, and 204 are disposed, and beneath the external through holes 18, on which the semiconductor devices 200, 201, 202, 203, and 204 are not disposed, in a plan view. To discharge voids in the encapsulation material 300 and the cavity 23, the window pattern 11 may be disposed beneath the internal through holes 17. Because the encapsulation material 300 seals even the lower surfaces of the semiconductor devices 200, 201, 202, 203, and 204 in a semiconductor MUF process, the PCB 100 includes the internal through holes 17 that act as a passage for the encapsulation material 300 such that the encapsulation material 300 seals the lower surfaces of the semiconductor devices 200, 201, 202, 203, and 204, and the window pattern 11 may be disposed beneath the internal through holes 17 such that voids in the encapsulation material 300 and the cavity 23 may be discharged. Eventually, the encapsulation material 300 may fill the cavity 23, the internal through holes 17, and the window pattern 11 of the molding apparatus 1. As described above, the window pattern 11 is a passage through which voids and the encapsulation material 300 in the cavity 23 are discharged, and by using the window pattern 11, the semiconductor devices 200, 201, 202, 203, and 204 may be sealed with the encapsulation material 300. Because the window pattern 11 needs to exist beneath each of the internal through holes 17 of the PCB 100, the window pattern 11 may be aligned with the internal through holes 17. Unlike the internal through holes 17, at least some of the external through holes 18 may be physically spaced apart from the semiconductor devices 200, 201, 202, 203, and 204 in a plan view. The external through holes 18 may be formed at substantially the same vertical level as that of the internal through holes 17 and perform the same function as the internal through holes 17. However, in embodiments of the present inventive concept, the sizes of the external through holes 18 may be different from the sizes of the internal through holes 17, and this is described below with reference to FIG. 4. In the specification, the size of a through hole may be related to the diameter of the through hole.

Referring to FIG. 2, the encapsulation material 300 is injected through the runner 30. The encapsulation material 300 may be, for example, an epoxy molding compound (EMC), but the present inventive concept is not limited thereto. The encapsulation material 300 is injected in a liquid phase by applying heat to the encapsulation material 300 and then hardened later to be in a solid phase. The injected encapsulation material 300 may fill the cavity 23 to seal the semiconductor devices 200, 201, 202, 203, and 204.

In this case, as shown by arrows shown in FIG. 2, the encapsulation material 300 may flow between the semiconductor devices 200, 201, 202, 203, and 204 and the PCB 100. The encapsulation material 300 may seal the semiconductor device 200. A portion of the encapsulation material 300 may flow to the window pattern 11 through an internal through hole 17, and the other portion of the encapsulation material 300 may move to seal the semiconductor device 201 at a next position.

Next, the encapsulation material 300 may seal the semiconductor device 201. A portion of the encapsulation material 300 may flow to the window pattern 11 through an internal through hole 17, and the other portion of the encapsulation material 300 may move to seal the semiconductor device 202 at a next position.

For the semiconductor devices 202 and 203 at next positions, the encapsulation material 300 may move with the same flow as when flowing to seal the semiconductor devices 200 and 201 at previous positions. Finally, the encapsulation material 300 may seal the semiconductor device 204 at the farthest position. A portion of the encapsulation material 300 may flow to the window pattern 11 through an internal through hole 17, and the other portion of the encapsulation material 300 may flow to the window pattern 11 through an external through hole 18.

In the semiconductor molding upper and lower molds 20 and 10, there is no portion through which voids and the like in the encapsulation material 300 and the cavity 23 are discharged except for the window pattern 11, and thus, the encapsulation material 300 may seal the semiconductor devices 200, 201, 202, 203, and 204. For example, the encapsulation material 300 For example, to seal the semiconductor devices 200, 201, 202, 203, and 204 without voids, the window pattern 11 may be a vacuum. When the window pattern 11 is a vacuum, the encapsulation material 300 may further smoothly flow.

When the encapsulation material 300 is injected into the molding apparatus 1 and fills a space that is between the cavity 23 and the semiconductor devices 200, 201, 202, 203, and 204 and voids, which may occur in this process, are also discharged through the internal through holes 17 and the external through holes 18, as shown in FIG. 3A, the molding apparatus 1 having the cavity 23 that is sealed with the encapsulation material 300 may be obtained.

Next, a top view of a PCB is described with reference to FIG. 3B.

As shown in FIG. 3B, a plurality of semiconductor devices 200 may be mounted on the PCB.

In FIG. 3B, a plurality of scribing lines SL may respectively surround the plurality of semiconductor devices 200 so that the semiconductor devices 200 may be individually separated later, and a portion surrounded by a line M1 may be a first portion that is a first area in which an encapsulation material is formed on the PCB. For example, the line M1 may be a mark indicating the boundary of a portion where the encapsulation material is formed. The first portion may be included in an area of the PCB in a plan view. The boundary surface of the line M1 may face the outer surfaces of the plurality of semiconductor devices 200, and the external through holes 18 may be between the line M1 and the outer surfaces of the plurality of semiconductor devices 200.

The plurality of semiconductor devices 200 may include a plurality of semiconductor devices 200a, 200b, 200c, and 200d, and each of the plurality of semiconductor devices 200a, 200b, 200c, and 200d may be separated from each other in a post process and become a semiconductor device product.

FIG. 4 is a magnified cross-sectional view of a portion “EX” of FIG. 3B. Referring to FIG. 4, when the diameter of an internal through hole 17 is d1 and the diameter of an external through hole 18 is d2, d1 may be different from d2. For example, the diameter d2 of the external through hole 18 may be greater than the diameter d1 of the internal through hole 17.

In FIG. 4, when a line along which an edge of a semiconductor device 200 at the farthest position, of the semiconductor device 200, in a first direction in which the encapsulation material is injected, among the plurality of semiconductor devices 200, is indicated as a line A1 and a line along which the line M1 that is the boundary of the first area that is filled with the encapsulation material is indicated as a line A2, the external through hole 18 may be between the line A1 and the line A2. For example, the external through hole 18 may be in a region, which does not overlap the semiconductor device 200 in a plan view.

In embodiments of the present inventive concept, each of the internal through hole 17 and the external through hole 18 may have a diameter that is greater than or equal to about 120 μm so as to effectively discharge voids that are in the encapsulation material and the cavity 23 (see FIG. 1). The internal through hole 17 might not be formed to have a width that is greater than the width of the window pattern 11 (see FIG. 1), and the width of the window pattern 11 (see FIG. 1) may be about 600 μm.

As a result, the diameter d1 of the internal through hole 17 may be less than about 600 μm. For example, the diameter d1 of the internal through hole 17 may be within a range between about 120 μm and about 600 μm. However, because the diameter d2 of the external through hole 18 is not limited to the width of the window pattern 11 (see FIG. 1), the diameter d2 may be about 120 μm or greater.

Although FIG. 4 shows that the size of the external through hole 18 is greater than the size of the internal through hole 17, the size of the external through hole 18 may be the same as the size of the internal through hole 17. However, as the diameter of a through hole increases, the encapsulation material and voids in the molding apparatus 1 (see FIG. 1) may be effectively discharged, and thus, the size of the external through hole 18 may be greater than the size of the internal through hole 17 to further properly ensure the quality of the molding apparatus 1 (see FIG. 1).

Referring back to FIG. 4, the external through hole 18 may be between the line A1 and the line A2. The separated distance between the line A1 and the line A2 may be defined as d0. In this case, when a position at the center of the external through hole 18 is arranged is defined as A3, the distance between a line, which extends from the position A3 in the vertical direction, and the line A2 may be defined as d3. In embodiments of the present inventive concept, the external through hole 18 may be closer to the line A2 in a region that is between the line A1 and the line A2. For example, the distance d3 might not exceed half of the distance d0.

According to a position where the external through hole 18 is arranged, when the plurality of semiconductor devices 200 (see FIG. 3B) are divided into individual packages, some semiconductor devices 200 that are adjacent to the external through holes 18 may have a lower shape that is different from that of the other semiconductor devices 200 that are not adjacent to the external through holes 18. In a process of packaging and individually dividing semiconductor devices later, a portion of the external through hole 18 may be cut together. Therefore, to prevent a case where lower portions of some packages have a shape that is different from that of lower portions of the other packages even though semiconductor devices mounted on the same PCB are packaged, the external through hole 18 may also be additionally provided to spaces that are between semiconductor devices as described below with reference to FIG. 5.

FIG. 5 is a top view of a PCB according to embodiments of the present inventive concept. In FIG. 5, reference numerals that are similar to those of FIG. 3B, denote like members, and thus, their repetitive description is omitted or briefly discussed herein. Compared to the pattern top view of FIG. 3B, the pattern top view of FIG. 5 has differences in the number and the positions of external through holes 18, and thus, the differences are described.

Referring to FIG. 5, additional external through holes 18b may be arranged between the internal through holes 17. The diameter of an additional external through hole 18b may be the same as the diameter of an external through hole 18a at the farthest position among the external through holes 18a and 18b. Compared to FIG. 3B, the additional external through holes 18b additionally provided in FIG. 5 are provided to give consistency to the lower patterns of semiconductor packages when obtaining the semiconductor packages by individualizing the plurality of semiconductor devices 200 later, and thus, the additional external through holes 18b and external through holes 18a may have the same diameter as each other and be spaced apart by a certain distance from each other. Even in this case, each of the additional external through holes 18b may have a diameter that is different from a diameter of each of the internal through holes 17. In embodiments of the present inventive concept, each of the additional external through holes 18b may have a diameter that is greater than a diameter of each of the internal through holes 17.

Referring to FIGS. 1 to 3B, the encapsulation material 300 may seal a semiconductor device 200 and be discharged to the window pattern 11 or move to seal a next semiconductor device 200. For example, the encapsulation material 300 that is injected seals a first semiconductor device 200a. Then, a portion of the encapsulation material 300 may be discharged to the window pattern 11 through a first internal through hole 17a. In addition, another portion of the encapsulation material 300 may be discharged to the window pattern 11 through an adjacent external through hole 18, and the other portion of the encapsulation material 300 may move to seal a second semiconductor device 200b. The encapsulation material 300 that is discharged to the window pattern 11 may flow toward an air vent by passing through a reservoir in the first direction.

In the same manner as described above, the encapsulation material 300 may seal the second semiconductor device 200b, and a portion of the encapsulation material 300 may be discharged to the window pattern 11 through a second internal through hole 17b. In addition, another portion of the encapsulation material 300 may be discharged to the window pattern 11 through an adjacent external through hole 18, and the other portion of the encapsulation material 300 may move toward a third semiconductor device 200c.

In this manner, the encapsulation material 300 may sequentially mold the plurality of semiconductor devices 200 (i.e., in the order of first to fifth semiconductor devices 200a, 200b, 200c, and 200d) in an injected direction of the encapsulation material 300. According to the progress of a molding process, the encapsulation material 300 may sequentially flow through the first internal through hole 17a, the second internal through hole 17b, a third internal through hole 17c, a fourth internal through hole 17d, and an external through hole 18 at the farthest position and also flow through external through holes 18 additionally provided between the internal through holes 17. The process described above may also be applied to a case where the PCB shown in FIG. 5 is used. The semiconductor molding lower mold according to embodiments of the present inventive concept may have through holes in not only an internal area in which semiconductor devices are mounted but also an external area to effectively discharge voids, which may occur in a molding process, even without a separate dummy space for removing the voids. Therefore, the reliability of a device may be increased and an increased integration may also be anticipated. In addition, it may be designed that the diameter of each through hole in an external area is greater than the diameter of each through hole in an internal area, thereby anticipating increased void removal.

While the present inventive concept has been described with reference to embodiments thereof, it will be understood by those of ordinary skill in the art that various changes in form and details may be made thereto without departing from the spirit and scope of the present inventive concept.

What is claimed is:

1. A semiconductor device comprising:
a semiconductor molding upper mold and a semiconductor molding lower mold, wherein a printed circuit board having a plurality of semiconductor devices mounted thereon is disposed on the semiconductor molding lower mold; and
a cavity disposed between the semiconductor molding upper mold and the semiconductor molding lower mold,
wherein the printed circuit board comprises internal through holes and external through holes, wherein the external through holes are spaced apart from a position where the plurality of semiconductor devices are mounted, and the semiconductor molding lower mold has through holes that overlap the internal through holes and the external through holes.

2. The semiconductor device of claim 1, further comprising an encapsulation material that seals the plurality of semiconductor devices,
wherein the encapsulation material is injected into the cavity that is between the semiconductor molding upper mold and the semiconductor molding lower mold.

3. The semiconductor device of claim 1, wherein a diameter of each of the external through holes is greater than a diameter of each of the internal through holes.

4. The semiconductor device of claim 1, wherein a diameter of each of the internal through holes is about 120 μm or greater.

5. The semiconductor device of claim 1, wherein a diameter of each of the internal through holes is not greater than about 600 μm.

6. The semiconductor device of claim 1, wherein a separation distance between the internal through holes is constant.

7. The semiconductor device of claim 1, wherein the internal through holes are disposed under the plurality of semiconductor devices at the same positions as the plurality of semiconductor devices, respectively.

8. The semiconductor device of claim 1, wherein the plurality of semiconductor devices mounted on the printed circuit board include flip chips.

9. The semiconductor device of claim 1, wherein the external through holes are disposed outside of an area in which the internal through holes are arranged.

10. The semiconductor device of claim 1, wherein the external through holes are disposed between outer surfaces of outer semiconductor devices, which are disposed at the outermost side of an arrangement of the plurality of semiconductor devices, and an outer surface of the printed circuit board, and the outer surfaces of the outer semiconductor devices face the outer surface of the printed circuit board.

11. A semiconductor package comprising:
a printed circuit board including internal through holes and external through holes;
a plurality of semiconductor devices mounted on the printed circuit board; and
an encapsulation material sealing a space that is between the printed circuit board and the plurality of semiconductor devices,
wherein the internal through holes are disposed under the plurality of semiconductor devices, respectively, and the external through holes are disposed outside an area in which the plurality of semiconductor devices are mounted.

12. The semiconductor package of claim 11, wherein a diameter of each of the external through holes is about 120 μm or greater, and a diameter of each of the internal through holes is within a range of about 120 μm to about 600 μm.

13. The semiconductor package of claim 11, wherein a cross-section of each of the external through holes is a circular shape.

14. A printed circuit board comprising:
an upper surface, on which a plurality of semiconductor devices are mounted, and a lower surface that is opposite to the upper surface;
internal through holes disposed under the plurality of semiconductor devices, respectively; and
first external through holes disposed outside an area in which the internal through holes are arranged, wherein each of the first external through holes has a diameter that is greater than a diameter of each of the internal through holes.

15. The printed circuit board of claim 14, wherein the first external through holes are disposed between outer surfaces of outer semiconductor devices, which are disposed at the outermost side of an arrangement of the plurality of semiconductor devices, and an outer surface of the printed circuit board, and the outer surfaces of the outer semiconductor devices face the outer surface of the printed circuit board.

16. The printed circuit board of claim 14, wherein a first portion that is an area in which an encapsulation material is formed on the printed circuit board is included in an area of the printed circuit board in a plan view, a boundary surface of the first portion faces outer surfaces of outer semiconductor devices of the plurality of semiconductor devices, and the first external through holes are in an area between the boundary surface of the first portion and the outer surfaces of the outer semiconductor devices.

17. The printed circuit board of claim 16, wherein the first external through holes are in an area that is disposed between a central line and the boundary surface of the first portion, the central line bisecting a distance between the boundary surface of the first portion and the outer surfaces of the outer semiconductor devices.

18. The printed circuit board of claim 14, wherein a diameter of each of the first external through holes is about 120 μm or greater.

19. The printed circuit board of claim 14, wherein a diameter of each of the internal through holes is within a range of about 120 μm to about 600 μm.

20. The printed circuit board of claim 14, further comprising second external through holes disposed between the plurality of semiconductor devices.
